(19) United States
(12) Patent Application Publication
(10) Pub. No.: US 2008/0225500 A1
(43) Pub. Date: Sep. 18, 2008

(54) Printed circuit board unit and printed wiring board

(75) Inventors: Yasuhide Kuroda, Kawasaki (JP); Tetsuji Ishikawa, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/073,369

(22) Filed: Mar. 4, 2008

(30) Foreign Application Priority Data
Mar. 13, 2007 (JP) 2007-064004

(51) Int. Cl. H05K 7/12

(52) U.S. Cl. 361/767; 361/752

(57) ABSTRACT

An electronic component has a pair of electrically-conductive terminals. Electrically-conductive pads are opposed to each other on the surface of a substrate at the inner edges defined along parallel first reference lines. Solder is placed on the electrically-conductive pads for bonding the electrically-conductive terminals to the electrically-conductive pads, respectively. The electrically-conductive pad includes protruding sections formed continuous with a main section having the side edges along parallel second reference lines intersecting with the first reference lines. The protruding sections protrude outside the second reference lines along corresponding one of the first reference line. The surface tensions of the melted solder on the main section and the protruding sections are balanced with each other. The electronic component is thus prevented from standing up. The electronic component is prevented from suffering from tombstone phenomenon.

### BACKGROUND OF THE INVENTION

1. Field of the Invention

The present invention relates to a printed circuit board unit including a substrate; electrically-conductive pads exposed on the surface of the substrate at a predetermined interval; an electronic component having a pair of electrically-conductive terminals at opposite ends; and solder serving to bond the electrically-conductive terminals to the electrically-conductive pads, respectively.

2. Description of the Prior Art

A pair of electrically-conductive pads is exposed on the surface of a substrate at a predetermined interval, as disclosed in the Japanese Patent Application Publication No. 6-6021, for example. The electrically-conductive pads are placed within separate openings defined in a resist film, respectively. The resist film serves to prevent the electrically-conductive pads from suffering from so-called bridging of solder between the electrically-conductive pads. An electronic chip, such as a chip capacitor, has electrodes placed on the corresponding electrically-conductive pads, respectively. Solder is utilized to bond the electrodes to the corresponding electrically-conductive pads, respectively. The chip capacitor is in this manner mounted on the substrate.

A cream solder is applied to the electrically-conductive pads when the chip capacitor is to be mounted. The chip capacitor is placed on the cream solder. A reflow process enables the cream solder to melt. The melted solder forms a fillet along the individual electrically-conductive terminal. The fillet serves to apply the surface tension of the melted solder to the chip capacitor. Unless the cream solder is simultaneously melted on both the electrically-conductive pads, the chip capacitor suffers from the unbalanced surface tension applied from the melted solder on the electrically-conductive pads. The chip capacitor stands up in response to the unbalanced surface tension. So-called tombstone phenomenon occurs.

In addition, if the thickness of the resist film is increased at a position between the electrically-conductive pads, the resist film receives the bottom of the chip capacitor. The chip capacitor is thus inclined around the resist film based on the imbalance of the surface tension. Tombstone phenomenon occurs.

### SUMMARY OF THE INVENTION

It is accordingly an object of the present invention to provide a printed circuit board unit and a printed wiring board both reliably contributing to prevention of tombstone phenomenon.

According to a first aspect of the present invention, there is provided a printed circuit board unit comprising: a substrate; an electronic component having a pair of electrically-conductive terminals at the opposite ends; a pair of electrically-conductive pads exposed on the surface of the substrate, the electrically-conductive pads opposed to each other at the inner edges defined a long a pair of first reference lines extending in parallel with each other at a predetermined interval; and solder placed on the electrically-conductive pads for bonding the electrically-conductive terminals to the electrically-conductive pads, respectively, wherein the electrically-conductive pads each include: a main section defining the side edges extending along a pair of second reference lines extending in parallel with each other, the second reference lines intersecting with the first reference lines; and protruding sections formed continuous with the main section, the protruding sections protruding outside the second reference lines along corresponding one of the first reference line.

When the printed circuit board unit is to be produced, a cream solder is applied to the electrically-conductive pads, for example. The electronic component is placed on the cream solder. Heat is applied to the cream solder so that the cream solder melts. The melted solder forms a fillet on the individual electrically-conductive pad. The fillet serves to generate the surface tension of the melted solder. The surface tension of the melted solder on the main section serves to pull the electronic component toward the outer edge of the main section. Likewise, the surface tension of the melted solder on the protruding sections serves to pull the electronic component toward the protruding sections. The surface tension in the opposite directions is thus balanced with each other. The electronic component is thus prevented from standing up. The electronic component is prevented from suffering from tombstone phenomenon.

Moreover, the melted solder is allowed to flow from the main section to the protruding sections. The melted solder is thus prevented from flowing outside the inner edge of the main section toward the exposed surface of the substrate. In addition, the melted solder on the protruding sections serves to bond the individual electrically-conductive terminal to the corresponding electrically-conductive pad. The interval can be increased between the inner edges of the main sections in a space between the electrically-conductive pads. This results in prevention of so-called bridging of the melted solder. Establishment of the resist film is thus refrained between the electrically-conductive pads.

The width of the main section, measured along the corresponding one of the first reference lines, gets smaller as the position gets farther outward from the end of the electronic component. The printed circuit board unit enables reduction in the surface tension near the outer edge of the main section as compared with the case where the main section has a constant width. The electronic component is thus reliably prevented from suffering from tombstone phenomenon.

The width of the individual protruding section, measured along the second reference line, may get smaller as the position gets farther outward from the second reference line. The printed circuit board unit allows the melted solder to smoothly flow from the main section to the protruding sections. The melted solder is prevented from flowing outside the inner edge of the main section to the exposed surface of the substrate. This results in prevention of so-called bridging of the solder.

The rear ends of the electrically-conductive terminals may respectively be placed on the main sections at a position established between the protruding sections. The inner end of the main section may be defined along an arc expanding toward the outer end of the main section. The printed circuit board unit allows the melted solder to smoothly flow from the main section to the protruding sections. The melted solder is prevented from flowing outside the inner edge of the main section to the exposed surface of the substrate. This results in prevention of so-called bridging of the solder.

The substrate may include an insulating film covering over the main section at a position outside the contour of the electronic component, the insulating film defining at least part of the contour of the main section. The printed circuit board unit ensures the surface area of the electrically-conductive pads exposed within the opening as sufficiently as the aforementioned printed circuit board unit. The contact area can be increased between the electrically-conductive pads and the substrate. This results in enhancement of the bonding strength between the electrically-conductive pads and the surface of the substrate. The electrically-conductive pads are thus reliably prevented from detachment.

The printed circuit board unit may be incorporated in an electronic apparatus. The electronic apparatus may comprise: an enclosure; a substrate enclosed in the enclosure; an electronic component having a pair of electrically-conductive terminals at the opposite ends; a pair of electrically-conductive pads exposed on the surface of the substrate, the electrically-conductive pads opposed to each other at inner edges defined along a pair of first reference lines extending in parallel with each other at a predetermined interval; and solder placed on the electrically-conductive pads for bonding the electrically-conductive terminals to the electrically-conductive pads, respectively, wherein the electrically-conductive pads each include: a main section defining the side edges extending along a pair of second reference lines extending in parallel with each other, the second reference lines intersecting with the first reference line; and protruding sections formed continuous with the main section, the protruding sections protruding outside the second reference lines along corresponding one of the first reference line.

According to a second aspect of the present invention, there is provided a printed wiring board comprising: a substrate; a pair of electrically-conductive pads exposed on the surface of the substrate, the electrically-conductive pads opposed to each other at the inner edges defined along a pair of first reference lines extending in parallel with each other at a predetermined interval, wherein the electrically-conductive pads each include: a main section defining the side edges extending along a pair of second reference lines extending in parallel with each other, the second reference lines intersecting with the first reference lines; and protruding sections formed continuous with the main section, the protruding sections protruding outside the second reference lines along corresponding one of the first reference line. The printed wiring board of this type contributes to realization of the aforementioned printed circuit board unit.

### BRIEF DESCRIPTION OF THE DRAWINGS

The above and other objects, features and advantages of the present invention will become apparent from the following description of the preferred embodiments in conjunction with the accompanying drawings, wherein:

FIG. 1 is a perspective view schematically illustrating a server computer apparatus as a specific example of an electronic apparatus according to the present invention;

FIG. 2 is an enlarged partial perspective view schematically illustrating a printed circuit board unit according to a first embodiment of the present invention;

FIG. 3 is a sectional view taken along the line 3-3 in FIG. 2;

FIG. 4 is a plan view schematically illustrating the printed circuit board unit according to the first embodiment of the present invention;

FIG. 5 is a plan view schematically illustrating a printed circuit board unit according to a second embodiment of the present invention;

FIG. 6 is a plan view schematically illustrating a printed circuit board unit according to a third embodiment of the present invention;

FIG. 7 is a plan view schematically illustrating a printed circuit board unit according to a fourth embodiment of the present invention;

FIG. 8 is a plan view schematically illustrating a printed circuit board unit according to a fifth embodiment of the present invention;

FIG. 9 is a plan view schematically illustrating a printed circuit board unit according to a modified example of the fifth embodiment;

FIG. 10 is a plan view schematically illustrating a printed circuit board unit according to a sixth embodiment of the present invention;

FIG. 11 is a sectional view taken along the line 11-11 in FIG. 10;

FIG. 12 is a plan view schematically illustrating a printed circuit board unit according to a seventh embodiment of the present invention;

FIG. 13 is an enlarged sectional view schematically illustrating a printed circuit board unit according to an eighth embodiment of the present invention; and

FIG. 14 is a plan view schematically illustrating a printed circuit board unit according to a modified example.

### DESCRIPTION OF THE PREFERRED EMBODIMENTS

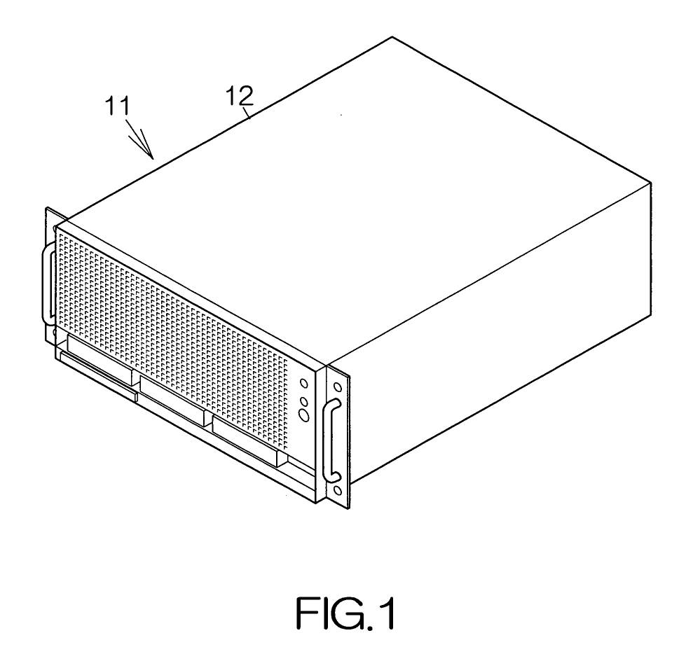

FIG. 1 schematically illustrates a server computer apparatus 11 as a specific example of an electronic apparatus. The server computer apparatus 11 includes an enclosure 12 defining an inner space. A printed circuit board unit is enclosed in the enclosure 12, as described later in detail. The printed circuit board unit includes a semiconductor chip package and a main memory. The semiconductor chip package executes various kinds of processing based on software programs and/or data temporarily held in the main memory, for example. The software programs and/or data may be stored in a mass storage such as a hard disk drive (HDD) likewise enclosed in the enclosure 12. The server computer apparatus 11 is mounted on a rack, for example.

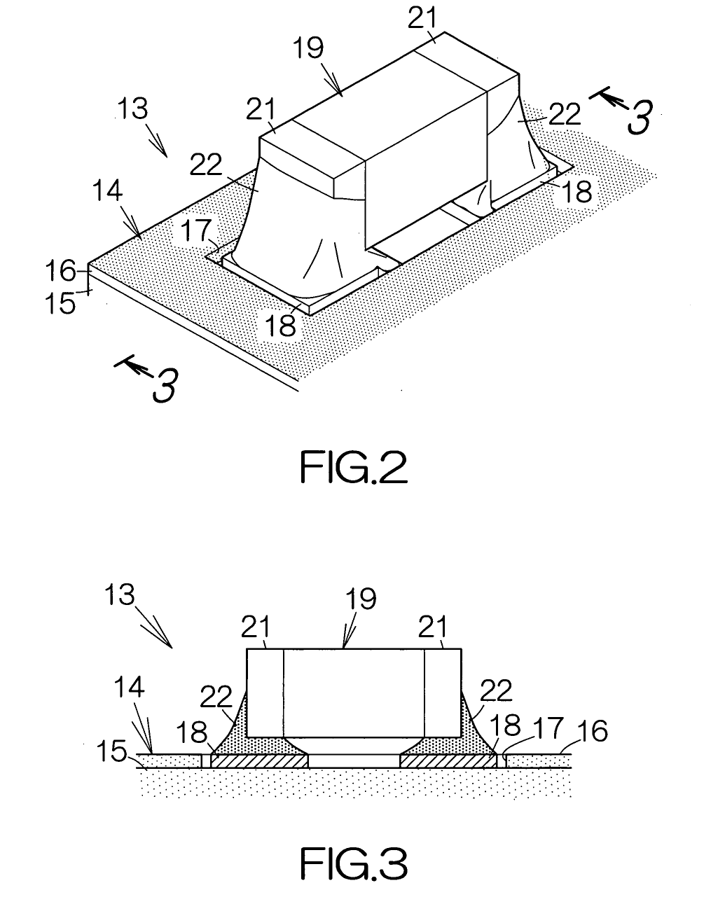

As shown in FIG. 2, a printed circuit board unit 13 according to a first embodiment of the present invention includes a printed wiring board 14. The printed wiring board 14 includes a substrate 15 made of resin, for example. An insulating film, namely a resist film 16, covers over the surface of the substrate 15. The resist film 16 is made of a resin material such as an epoxy resin, a polyimide resin, or the like. A rectangular opening 17 is formed in the resin film 16, for example. A pair of electrically-conductive pads, namely footprint patterns 18, 18, is formed on the surface of the substrate 15. The footprint patterns 18 are exposed within the opening 17. The footprint patterns 18 are spaced from each other at a predetermined interval. The footprint patterns 18 are made of an electrically-conductive material such as copper.

An electronic chip, namely a chip capacitor 19, is placed on the footprint patterns 18. The chip capacitor 19 is shaped in a rectangular parallelepiped, for example. The chip capacitor 19 is electrically charged. The chip capacitor 19 takes the chip size of so-called 0603 type or 0402 type. The thickness of the chip capacitor 19 is set at 0.2 mm or 0.3 mm, for example. The chip capacitor 19 has a pair of electrically-conductive terminals or electrodes 21 at the opposite ends of the chip capacitor 19. The electrodes 21 are placed on the corresponding footprint patterns 18, respectively. Solder 22 is utilized to bond the electrodes 21 to the corresponding footprint patterns 18, respectively. Electrical connection is in this manner established between the electrodes 21 and the corresponding footprint patterns 18, respectively. The chip capacitor 19 is mounted on the printed wiring board 14. It should be noted that the electronic chip also includes a chip coil, a chip resistor, and the like, for example. The chip coil and chip resistor are likewise mounted on the printed wiring board 14 in the same manner as the chip capacitor 19.

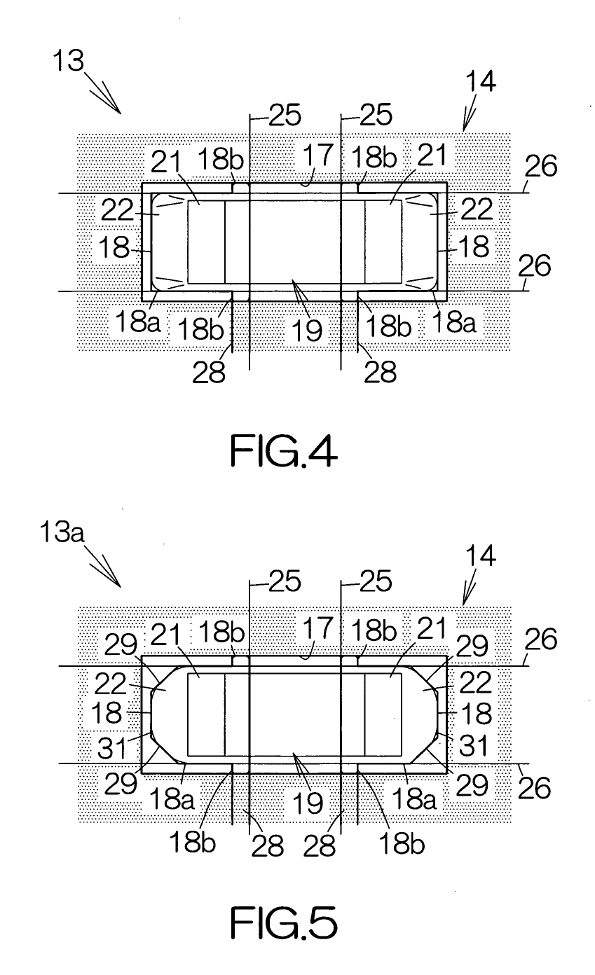

As shown in FIG. 3, establishment of the resist film 16 is refrained between the footprint patterns 18. The surfaces of the footprint patterns 18 are defined within the opening 17 at a predetermined level above the surface of the substrate 15. Referring also to FIG. 4, the footprint patterns 18 are placed inside the contour of the opening 17. The footprint patterns 18 define the inner edges extending along a pair of first reference lines 25, 25, respectively. The footprint patterns 18 are opposed to each other at the inner edges. The first reference lines 25, 25 extend in parallel with each other at a predetermined interval. The first reference lines 25 extend across the opening 17 in parallel with the shorter sides of the rectangular opening 17.

The individual footprint pattern 18 defines a main section 18a having side edges defined along a pair of second reference lines 26, 26 perpendicular to the first reference lines 25. The second reference lines 26 extend in parallel with each other. The second reference lines 26 are defined outside the contour of the chip capacitor 19. The main section 18a has a rectangular contour, for example. The inner edge of the main section 18a is placed at a position between the electrodes 21 of the chip capacitor 19. The outer edge of the main section 18a is defined outside the corresponding electrode 21 of the chip capacitor 19. The outer edge of the main section 18a may be defined in parallel with the inner edge of the main section 18a.

The individual footprint patterns 18 define a pair of protruding sections 18b continuous with the main section 18a. The protruding sections 18b protrude outside the second reference lines 26, 26 along the first reference line 25. Specifically, the protruding sections 18b protrude outward from the side edges of the main section 18a in the opposite directions. The protruding sections 18b are thus positioned outside the contour of the chip capacitor 19. The individual protruding section 18b may have a rectangular contour, for example. One of the protruding sections 18b is connected to an electrically-conductive pattern 28 formed on the surface of the substrate 15. The electrically-conductive pattern 28 is made of an electrically-conductive material such as copper, for example.

The printed wiring board 14 is first formed prior to the mounting of the chip capacitor 19. The footprint patterns 18 and the electrically-conductive patterns 28 are formed on the surface of the substrate 15 based on etching process, for example. The resist film 16 is then formed on the surface of the substrate 15. The opening 17 is defined in the resist film 16. The footprint patterns 18 are exposed within the opening 17. The solder 22 is printed on the footprint patterns 18 within the opening 17. A cream solder is employed as the solder 22, for example. The chip capacitor 19 is mounted on the solder 22.

Heat is applied to the solder 22 so that the solder 22 melts. The melted solder 22 forms a fillet on the individual footprint pattern 18. The fillet serves to generate the surface tension of the melted solder 22. The surface tension of the melted solder 22 on the main section 18a serves to pull the chip capacitor 19 toward the outer edge of the main section 18a. Likewise, the surface tension of the malted solder 22 on the protruding sections 18b serves to pull the chip capacitor 19 toward the protruding sections 18b. The surface tension in the opposite directions is thus balanced. The chip capacitor 19 is in this manner prevented from standing up. The chip capacitor is prevented from suffering from tombstone phenomenon.

Moreover, the melted solder 22 is allowed to flow to the protruding sections 18b from the main section 18a. The melted solder 22 is thus prevented from flowing outside the inner edge of the main section 18a toward the exposed surface of the substrate 15. In addition, the melted solder 22 on the protruding section 18b serves to bond the electrode 21 to the corresponding footprint pattern 18. The interval can be increased between the inner edges of the main sections 18a in a space between the footprint patterns 18, 18. This results in prevention of so-called bridging of the solder 22. Establishment of the resist film 16 can thus be refrained between the footprint patterns 18.

As shown in FIG. 5, the width of the individual main section 18a, measured in parallel with the first reference line 25, gets smaller as the position gets farther outward from the first reference line 25 in a printed circuit board unit 13a according to a second embodiment of the present invention. Here, the corners of the main section 18a are chamfered. The outer edge of the main section 18a thus includes a pair of inclined straight lines 29, 29 and a straight line 31 connecting the inclined straight lines 29, 29 to each other. Like reference numerals are attached to the structure or components equivalent to those of the aforementioned printed circuit board unit 13. The printed circuit board unit 13a enables reduction in the surface tension near the outer edge of the main section 18a as compared with the case where the main section 18a has a constant width. The chip capacitor 19 is thus reliably prevented from suffering from tombstone phenomenon.

As shown in FIG. 6, the outer edge of the individual main section 18a extends along a predetermined semicircle for establishment of the aforementioned reduction in the width of the main section 18a in a printed circuit board unit 13b according to a third embodiment of the present invention. Like reference numerals are attached to the structure or components equivalent to those of the aforementioned printed circuit board unit 13a. The printed circuit board unit 13b enables reduction in the surface tension near the outer edge of the main section 18a as compared with the case where the main section 18a has a constant width in the same manner as described above. The chip capacitor 19 is thus reliably prevented from suffering from tombstone phenomenon.

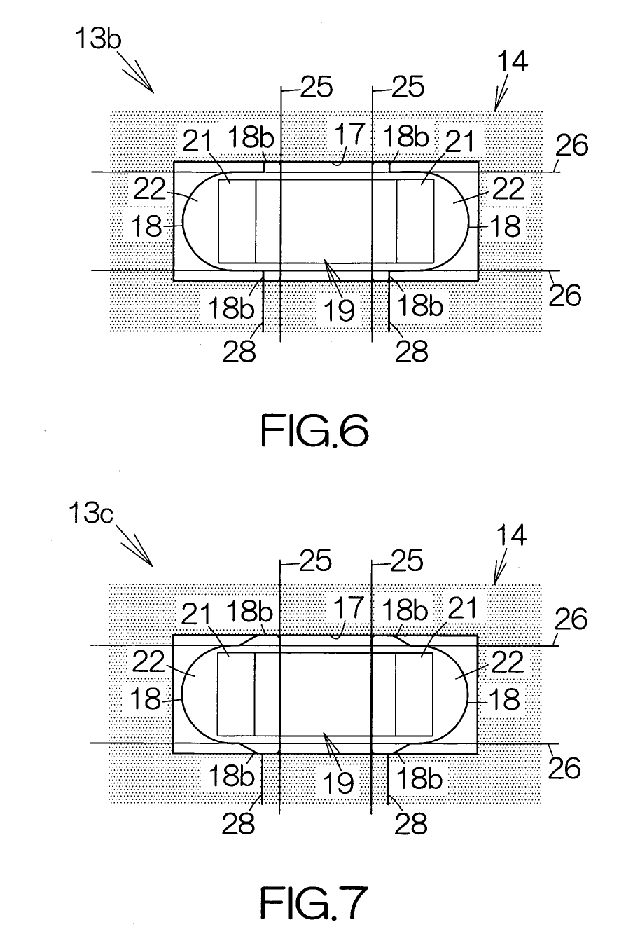

As shown in FIG. 7, the width of the individual protruding section 18b, measured in parallel with the second reference line 26, gets smaller as the position gets farther outward from the second reference line 26 in a printed circuit board unit 13c according to a fourth embodiment of the present invention. The outer edge of the protruding section 18b may intersect with the second reference line 26 at a predetermined inclination angle. In this case, the area of the protruding section 18b may preferably be set larger than that of the protruding section 18b of the aforementioned printed circuit board units 13, 13a, 13b. Like reference numerals are attached to the structure or components equivalent to those of the aforementioned printed circuit board units 13, 13a, 13b. The printed circuit board unit 13c enables an increased surface tension of the melted solder 22 on the protruding section 18b based on the increased area of the protruding section 18b. The chip capacitor 19 is thus reliably prevented from suffering from tombstone phenomenon. In addition, the melted solder 22 smoothly flows from the main sections 18a to the protruding sections 18b. The melted solder 22 is thus prevented from flowing outside the inner edges of the main sections 18a to the exposed surface of the substrate 15. This results in prevention of so-called bridging of the solder 22.

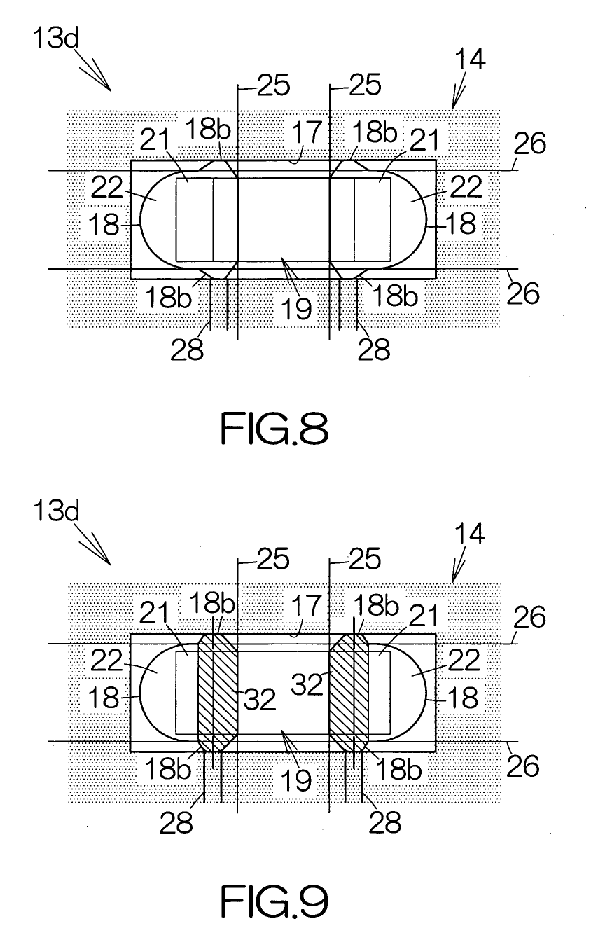

As shown in FIG. 8, not only the outer edge but also the inner edge of the individual protruding section 18b may intersect with the second reference line 26 at a predetermined inclination angle for establishment of the aforementioned reduction in the width of the protruding section 18b in a printed circuit board unit 13d according to a fifth embodiment of the present invention. Like reference numerals are attached to the structure or components equivalent to those of the aforementioned printed circuit board unit 13c. The printed circuit board unit 13d enables an increased surface tension of the melted solder 22 on the protruding section 18b based on the increased area of the protruding section 18b. The chip capacitor 19 is thus reliably prevented from suffering from tombstone phenomenon. In addition, the melted solder 22 smoothly flows from the main sections 18a to the protruding sections 18b. The melted solder 22 is thus prevented from flowing outside the inner edges of the main sections 18a to the exposed surface of the substrate 15. This results in prevention of so-called bridging of the solder 22.

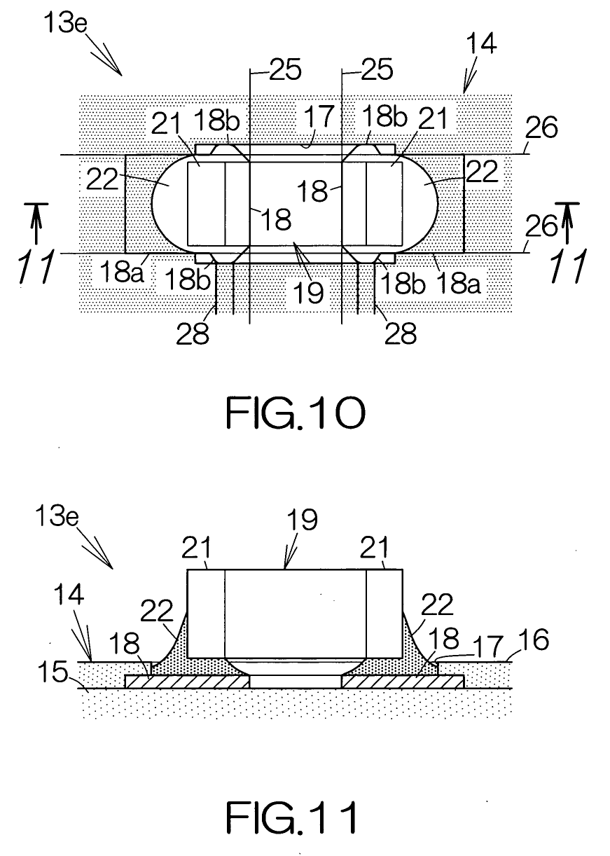

As shown in FIG. 9, the inner edges of the electrodes 21 of the chip capacitor 19 may be placed on a section 32 established between the protruding sections 18b, 18b. Here, an imaginary plane including the inner edge of the electrode 21 may extend across the intermediate positions of the side edges of the protruding sections 18b, for example. It should be noted that the inner edge of the electrode 21 is placed outside the inner edge of the main section 18a.

As shown in FIG. 10, the edges of the opening 17 may define the outer edges of the main sections 18a in a printed circuit board unit 13e according to a sixth embodiment of the present invention. Referring also to FIG. 11, the main sections 18a are partly covered with the resist film 16. The outer edge of the individual main section 18a may extend along a predetermined are based on the periphery of the resist film 16, for example. The main sections 18-a may have a rectangular contour. Like reference numerals are attached to the structure or components equivalent to those of the aforementioned printed circuit board units 13, 13a-13d. The printed circuit board unit 13e ensures the surface area of the footprint patterns 18 exposed within the opening 17 as sufficiently as the aforementioned printed circuit board units 13, 13a-13d. The contact area can be increased between the individual footprint pattern 18 and the substrate 15. This results in enhancement of the bonding strength between the footprint patterns 18 and the surface of the substrate 15. The footprint patterns 18 are thus reliably prevented from detachment.

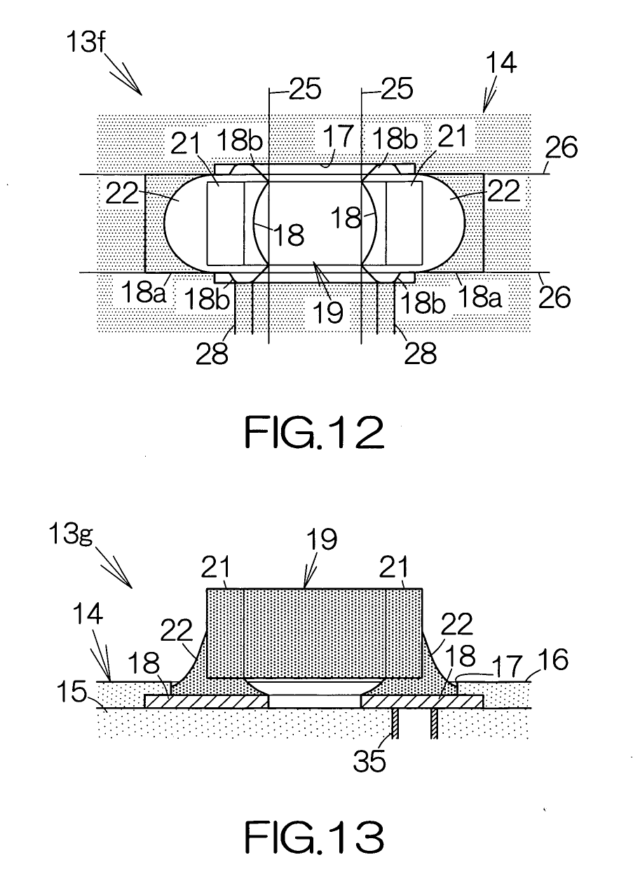

As shown in FIG. 12, the inner edge of the individual main section 18a may extend along a predetermined are in a printed circuit board unit 13f according to a seventh embodiment of the present invention. The predetermined arc expands toward the outer edge of the main section 18a. Like reference numerals are attached to the structure or components equivalent to those of the aforementioned printed circuit board unit 13e. The printed circuit board unit 13f allows the melted solder 22 to smoothly flow to the protruding sections 18b along the inner edge of the individual main section 18a. The melted solder 22 is prevented from flowing outside the inner edge of the individual main section 18a to the exposed surface of the substrate 15. This results in prevention of so-called bridging of the solder 22.

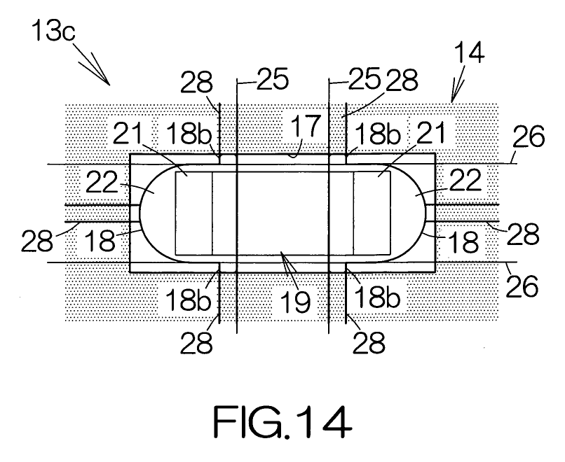

As shown in FIG. 13, the footprint pattern 18 may be connected to a via 35 formed in the substrate 15, in place of the aforementioned electrically-conductive pattern 28, in a printed circuit board unit 13g according to an eighth embodiment of the present invention. Like reference numerals are attached to the structure or components equivalent to those of the aforementioned printed circuit board units 13, 13a-13f. As shown in FIG. 14, two or more electrically-conductive patterns 28 may be connected to the footprint pattern or patterns 18. The via 35 may also be connected to the footprint pattern 18 in addition to the electrically-conductive patterns 28.

Various kinds of design are available for the aforementioned printed circuit board units 13, 13a-13g. The outer edge of the main section 18a may include a pair of inclined straight lines 29, 29 and the straight line 31 connecting the inclined straight lines 29, 29 to each other in the printed circuit board units 13b-13g, for example. The inner edge of the main section 18a may extend along a predetermined are in the printed circuit board units 13, 13a-13e, for example.

What is claimed is:

1. A printed circuit board unit comprising:
a substrate;
an electronic component having a pair of electrically-conductive terminals at opposite ends;
a pair of electrically-conductive pads exposed on a surface of the substrate, the electrically-conductive pads opposed to each other at inner edges defined along a pair of first reference lines extending in parallel with each other at a predetermined interval; and
solder placed on the electrically-conductive pads for bonding the electrically-conductive terminals to the electrically-conductive pads, respectively, wherein
the electrically-conductive pads each include:
a main section defining side edges extending along a pair of second reference lines extending in parallel with each other, the second reference lines intersecting with the first reference lines; and
protruding sections formed continuous with the main section, the protruding sections protruding outside the second reference lines along corresponding one of the first reference line.

2. The printed circuit board unit according to claim 1, wherein a width of the main section, measured along the corresponding one of the first reference lines, gets smaller as position gets farther outward from an end of the electronic component.

3. The printed circuit board unit according to claim 1, wherein a width of each of the protruding sections, measured along the second reference line, gets smaller as position gets farther outward from the second reference line.

4. The printed circuit board unit according to claim 1, wherein rear ends of the electrically-conductive terminals are respectively placed on the main sections at a position established between the protruding sections.

5. The printed circuit board unit according to claim 1, wherein an inner end of the main section is defined along an arc expanding toward an outer end of the main section.

6. The printed circuit board unit according to claim 1, wherein the substrate includes an insulating film covering over the main section at a position outside a contour of the electronic component, the insulating film defining at least part of a contour of the main section.

7. An electronic apparatus comprising:
an enclosure;
a substrate enclosed in the enclosure;
an electronic component having a pair of electrically-conductive terminals at opposite ends;
a pair of electrically-conductive pads exposed on a surface of the substrate, the electrically-conductive pads opposed to each other at inner edges defined along a pair of first reference lines extending in parallel with each other at a predetermined interval; and
solder placed on the electrically-conductive pads for bonding the electrically-conductive terminals to the electrically-conductive pads, respectively, wherein
the electrically-conductive pads each include:
a main section defining side edges extending along a pair of second reference lines extending in parallel with each other, the second reference lines intersecting with the first reference line; and
protruding sections formed continuous with the main section, the protruding sections protruding outside the second reference lines along corresponding one of the first reference line.

8. A printed wiring board comprising:
a substrate;
a pair of electrically-conductive pads exposed on a surface of the substrate, the electrically-conductive pads opposed to each other at inner edges defined along a pair of first reference lines extending in parallel with each other at a predetermined interval, wherein
the electrically-conductive pads each include:
a main section defining side edges extending along a pair of second reference lines extending in parallel with each other, the second reference lines intersecting with the first reference lines; and
protruding sections formed continuous with the main section, the protruding sections protruding outside the second reference lines along corresponding one of the first reference line.

9. The printed wiring board according to claim 8, wherein a width of the main section, measured along the corresponding one of the first reference lines, gets smaller as position gets farther outward from the corresponding one of the first reference lines.

10. The printed wiring board according to claim 8, wherein a width of each of the protruding sections, measured along corresponding one of the second reference lines, gets smaller as position gets farther outward from the corresponding one of the second reference lines.

11. The printed wiring board according to claim 8, wherein rear ends of the electrically-conductive terminals are respectively placed on the main section at a position established between the protruding sections.

12. The printed wiring board according to claim 8, wherein an inner end of the main section is defined along an arc expanding toward an outer edge of the main section.

13. The printed wiring board according to claim 8, wherein the substrate includes an insulating film covering over the main section at a position outside a contour of an electronic component expected to be mounted on the substrate, the insulating film defining at least part of a contour of the main section.
